(19) United States
(12) Patent Application Publication
(10) Pub. No.: US 2004/0201036 A1
(43) Pub. Date: Oct. 14, 2004

(54) Electronic device with barium fluoride substrate

(76) Inventor: Kiki Ikossi, Alexandria, VA (US)

Correspondence Address: NAVAL RESEARCH LABORATORY, ASSOCIATE COUNSEL (PATENTS), CODE 1008.2, 4555 OVERLOOK AVENUE, S.W., WASHINGTON, DC, 20375-5320, US

(21) Appl. No.: 10/409,709

(22) Filed: Apr. 8, 2003

(51) Int. Cl. H01L 31/0328

(52) U.S. Cl. 257/189

(57) ABSTRACT

A high frequency, low power dissipation electronic device capable of operating at low voltage, and optoelectronic devices which includes a barium fluoride substrate, particularly BaF₂ substrate having crystallographic (100) contact surface, and at least two semiconducting layers disposed thereon particularly selected from compounds of elements of Groups II, III, IV, V and VI of the Periodic Table.

### FIELD OF THE INVENTION

This invention pertains to an electronic device with a barium fluoride (BaF₂) substrate and two or more semiconducting layers disposed on the substrate.

### DESCRIPTION OF THE RELATED ART

Development of electronic devices capable of high frequency operation at low voltages with low power dissipation is in high demand for military, medical and commercial applications. Mobile communications, remote sensors, medical instrumentation, medical implants and computing will benefit immensely from such a capability.

In addition to high frequency devices with low power dissipation, sensors, detectors and optoelectronic devices operating in the infrared wavelength region are in great demand for key military technology as well as communications and a plethora of commercial applications.

The semiconductor material enabling all these applications are semiconducting compounds, particularly of Group III and V elements of the Periodic Table, with relatively low band gaps that happen to have lattice constants near 6.1 A. The antimonide family, which include GaSb, InSb and AlSb, along with InAs, have some of the most favorable electronic properties for high frequency applications.

One of the basic requirements for a high frequency electronic device is the presence of a semi-insulating substrate. The ability to have a semi-insulating substrate minimizes device stray practices and permits utilization of the inherent material properties. The InP and GaAs lattice matched devices have been very successful for high frequency applications because of the ability to produce semi-insulating substrates. Unfortunately, the low bandgap of the 6.1 A semiconductor family does not allow a high resistivity or semi-insulating behavior. Consequently, a major issue for the 6.1 A based materials system is the lack of a semi-insulating, lattice matched substrate that will allow the III-V compound heterostructure layers, and other compounds, to be developed effectively either as grown or heterogeneously integrated for high frequency device applications.

U.S. Pat. No. 6,133,593 discloses a heterostructure field-effect transistor (HEMT) comprising a semi-insulating (100) GaAs substrate and the following layers disposed thereon serially: undoped buffer layer AlSb disposed on the substrate is used to accommodate 7% lattice mismatch with the substrate, p+—GaSb hole layer, AlSb buffer layer, InAs subchannel layer, AlSb barrier layer, InAs channel layer, AlSb barrier layer, InAs Si-doped layer, AlSb barrier layer, In_{0.4} Al_{0.6} As barrier layer, and InAs cap layer. This HEMT also includes a source and drain metallizations disposed on the InAs cap layer and a Schottky gate disposed on the In_{0.4} Al_{0.6} As barrier layer. A HEMT (HF) is characterized by a semiconducting substrate, a buffer layer disposed on the substrate, a channel layer disposed on the buffer layer, and a contact layer disposed on the channel layer. If a HEMT has a sub-channel, it is disposed below the channel layer. In this application, the GaAs substrate is semi-insulating, has 7.9% lattice mismatch with the AlSb and 6.7% with InAs layers. The consequence of the large lattice mismatch is the generation of crystal defects, like slip and screw dislocations and point defects that reduce the device yield per wafer and prohibits their use in integrated circuit applications. p Published U.S. patent application Ser. No. 20020070390 discloses a heterojunction bipolar transistor (HBT) comprising a semi-insulating substrate, such as GaAs, and the following layers disposed thereon serially: n-doped collector layer AlSb, p-doped GaSb base layer, and an n-doped emitter layer InAs/AlSb. In the above document, the 6.1 Å lattice matched HBT is characterized by a conducting substrate; a sub-collector and a collector layer disposed on the substrate, with the sub-collector being in direct physical contact with the substrate; a base layer disposed over the collector layer; and an emitter contact and an emitter layers disposed on the base, with the emitter layer being in direct physical contact with the base. In an npn HBT, the emitter and the collector layers are n-doped whereas the base is p-doped, however, in an pnp HBT, the emitter and the collector layers are p-doped and the base layer is n-doped. In general, the current gain in the HBT comes from the band alignment between the base and emitter as well as between the base and collector. For an npn HBT, the base and emitter have to have a large valence band discontinuity to prevent holes from entering the emitter layer. In a conventional HBT or S-HBT, the base and collector layers are of similar material making a homojunction. In a double HBT (DHBT) the base and collector is a heterojunction. In an npn DHBT, the base collector conduction band discontinuity has to be as small as possible so that electrons from the base can easily flow in the collector. In general, the base is a smaller bandgap material than the emitter and in DHBT, the base bandgap is smaller than the collector band gap as well.

Today's commercial technology can produce HEMT operating at about 200 GHz and is typically faster than commercial HBT. Experimental HBTs have been reported operating with cut-off frequency of up to 800 GHz. Depending on material technology, high power HEMT and HBTs can reach power levels as high as several watts in specialized device configurations. In general HBTs being a current driven device can deliver, more power than a HEMT and suffers from less noise issues.

The technology disclosed herein is believed to be superior to the prior art technologies based on Si, GaAs and InP In terms of high frequency. The closest prior art is believed to be electronic devices characterized by an InP-based substrate with semiconducting layers disposed thereon selected from InAlAs, InGaAs, InP, GaAsSb, and the like. Generally, however, the closest prior art appears to be deposition of InSb on (111) face of BaF₂ that was not lattice matched, with lattice constant of BaF₂ being nearly 6.2 Å and that of InSb being nearly 6.5 Å.

### OBJECTS AND BRIEF SUMMARY OF THE INVENTION

An object of this invention is an electronic device that can operate at high frequency, at low power loss and requires low voltage for actuation.

Another object of this invention is a solid state low noise amplifier that operates at frequency above 300 GHz.

Another object of this invention is a high speed divider circuit operating below 100 GHz while consuming as little as about 6 mW dc power or one that can achieve multiplexing/demultiplexing at more than 80 G bps.

Another object of this invention is high speed, high frequency electronic components that can greatly expand the use of electromagnetic spectrum to enable wideband wireless communication and data links for various systems.

Another object of this invention is low power consumption electronics that can make feasible certain military and civilian commercial applications.

Another object of this invention is the ultra low power electronics that can increase the micro Unmanned Air Vehicles (UAVs) dwell time and performance and make certain long-life portable military and civilian systems feasible and affordable.

Another object of this invention is a sub-millimeter low noise amplifier that can enable real-time atmospheric spectral analysis for biological agents as well as battlefield meteorology.

Another object of this invention is the higher frequency digital electronics for generating high speed Internet backbone.

Another object of this invention is having infrared detectors and sensors developed and integrated with driver circuits.

Another object of this invention is infrared optoelectronic devices and semiconductor lasers.

These and other objects of this invention can be attained by an electronic device which includes a BaF₂ substrate, particularly BaF₂ substrate with a (100) crystallographic contact face, and at least two semiconducting layers, particularly compounds of elements selected from Groups III and V of the Periodic Table, disposed on the substrate.

### DETAILED DESCRIPTION OF THE INVENTION

This invention is directed to an electronic device which can operate at high frequency in the Tera Hertz region (10¹²), at low power dissipation which is at least a 50% improvement over the prior art, and at a low operating voltage of less than about 1 volt. More specifically, this invention pertains to an electronic device comprising an insulating, crystalline and an optically transparent BaF₂ substrate and at least two semiconducting layers disposed over the substrate. The semiconducting layers can be any suitable compounds but are particularly selected from compounds of elements selected from Groups II, III, IV, V and VI of the Periodic Table, and especially from compounds of elements of Groups III and V of the Periodic Table. Suitable specific compounds include compounds of the antimonide family and such compounds as InAs, GaSb, AlSb, InSb, ZnTa (II-VI), CdSe (II-VI), IV-VI compounds and the like. AlSb reacts with moisture in the atmosphere and for that reason, cannot be produced as a substrate and whenever used as an intermediate layer it has to be protected by another stable material like GaSb. As an interlayer, AlSb can be insulating with a high breakdown voltage. The compounds can be binary, ternary, quaternary or any other compounds having a lattice constant in the approximate range of 6-6.5 Å, particularly about 6.1 Å. Of particular interest herein are antimonides such as GaSb, InSb, and AlSb, along with InAs, which have some of the most favorable electronic properties for low power dissipation, high frequency applications.

Although BaF₂ is generally suitable herein for use as a substrate for the electronic device capable of operation at high frequency, at low power dissipation and at low operating voltage, including the (111) crystallographic orientation, of particular significance is the (100) BaF₂ face centered cubic crystal structure with a lattice constant of 6.19 Å, with the lattice matched to the layer adhering thereto. As used herein, lattice match is meant to be a match of lattice constants to within about 5%, preferably less than ±4%. Good electrical properties result if lattice match between the substrate and the semiconducting layer on the substrate is achieved, the materials have same or similar lattice constants within about 5% of each other, on the basis of same thickness. If lattice match is not achieved, dislocations will be encountered, resulting in poor electrical performance which can prevent use of large areas of the device, as well as integrated circuit production, and result in lower device yield. An electrical device can contain layers that are lattice mismatched without serious defect problems if the layer thickness are kept below the critical thickness for defect generation. The critical thickness is a function of the lattice difference and the Young Modulus and the elastic constants of the materials. For example, GaSb can be theoretically deposited on GaAs substrates without dislocations if the thickness of the GaSb layer is below 13 Å. Although lattice constant of a BaF₂, or any other binary semiconducting compound, cannot be changed, lattice constants of other ternary or quaternary compounds disposed on the substrate can be changed, as by controlling the composition of the elements comprising the compound semiconductor during epitaxial deposition on the substrate.

The use of BaF₂ as a substrate in an electronic device was unexpected and no one thought of the possibility for the reason that it was a general belief that a material with dissimilar crystalline structure could not be grown epitaxially. In particular, the III-V semiconductors are of zincblende structure with covalent bonds while BaF₂ is a face-centered-cubic-structure with ionic bonds. It was discovered, however, that even dissimilar materials and dissimilar chemical bonding can be overcome and epitaxy is possible with suitable crystalline orientation and lattice constant.

Although continuing performance improvements with alternative technologies , such as GaAs, InP and SiGe are still possible, this technology has the best performance figure of merit for combined metrics of high speed, low power and large scale integration over all microelectronics semiconductor technologies.

The use of BaF₂ for high frequency electronic device is consonant with its insulating nature in that parasitic capacitance is eliminated. Furthermore, with typical resistivity of 722 Ω/□, hole mobility of 208 cm²/V-sec and hole carrier concentration of 4.2×10¹⁷/cm³ for GaSb on (100) BaF₂ substrate and typical resistivity of 1830 Ω/□, hole mobility of 80 cm²/V-sec and hole carrier concentration of 2.13×10¹⁷/cm³ for InGaSb on (100) BaF₂ substrate, showed that electrically active materials can be grown on BaF₂. The substrate in all cases was 19 mm×19 mm×1.5 mm and the semiconducting compound disposed on the substrate were coextensive with the substrate and their thickness was 1 micron. There were no Hall measurements for AlSb because it reacts with ambient humidity turning into high resistivity.

Although electrical properties are important in this context, i.e., the context of high frequency operation at low power loss and at low voltage, the most important consideration here is smoothness of surface, which implies smooth interfaces for heterostructures and high speed heterostructure devices. The feasibility of using BaF₂ substrate for the electronic devices was indicated by viewing optical images and atomic force images of GaSb grown by MBE on (100) face of BaF₂ as compared to same semiconductor compound, i.e., GaSb, grown also by MBE on GaSb.

Set forth below in Table I are certain physical properties for BaF₂ and some of the more pertinent binary compounds:

TABLE I

| | BaF₂ | InAs | GaSb | AISb | InSb |
|---|---|---|---|---|---|
| energy gap @ 300 K (eV) | >5 | 0.36 | 0.726 | 1.56 | 0.172 |
| lattice constant (Å) | 6.196 | 6.058 | 6.096 | 6.135 | 6.479 |
| LC difference vs BaF₂ | 0 | 0.138 | 0.100 | 0.060 | −0.283 |
| % LC difference vs BaF₂ | 0 | 2.27 | 1.64 | 0.99 | −4.37 |
| lattice constant @ 300 K (Å) | 6.23 | 6.07 | 6.11 | 6.14 | 6.49 |
| % LC diff. vs BaF₂ @ 300 K (Å) | 0 | 2.67 | 2.01 | 1.53 | −4.00 |
| linear thermal exp. coeff. /K (10⁻⁶) | 18.1 | 5.00 | 6.00 | | 5.00 |
| thermal conductivity (W/cmK) | 0.118 | 0.4 | 0.2 | | 0.5 |

In Table I, above, the given lattice constant (LC) is for (100) BaF₂, which is the same for the (111) BaF₂. In Table I, the smaller the energy gap for the semiconductors the smaller the turn on voltage needed for device actuation. The small band gap also facilitates thermal generation of carriers, high intrinsic carrier concentration and supports high conductivity and high leakage currents. Lattice constants for the substrate and the semiconductors at room temperature are around 6.1 Å although lattice constant for InSb is 6.479 Å at 300 K, the lattice constants are somewhat higher but the relative size appears to be about the same. Linear thermal expansion coefficient/K is on the order of 10⁻⁶ for the semiconducting compounds but for BaF2 it is about an order of magnitude larger at about 10⁻⁵. This physical property deterred early applications of BaF₂ due to concerns of possible delamination of the layers with thermal cycling. It appears that delamination is avoided if there is a relatively good lattice match between the substrate and the semiconducting compound grown on the substrate at the growth temperatures and room temperature. Materials with a low band gap, such as InSb, GaSb and InAs, typically require less energy to actuate a device.

The materials used, especially Sb and InAs, mainly determine power dissipation of a device. Power dissipation of an electronic device is in general dependent on the required voltage or current to put the device in the active region. The size of the band gap sets in general the maximum limit of the power needed to transfer a carrier from the conduction to the valence band. Therefore, for low power dissipation, low band gap (E_{g}) semiconductors, such as InAs, GaSb and InSb, are very favorable.

In fabricating the novel electronic device disclosed herein, standard fabrication procedure is used, but it is pertinent to note that the substrates obtained from commercial sources are to be epitaxial growth ready, which means that the substrates have a thin layer of an oxide which is burned-off before growth by initially heating the substrate to degas for up to about 1 hour at 350° C. at pressure of 10⁻⁷ Torr and then at 500° C. for 20 minutes before cooling to the growth temperature of 400° C. Besides MBE, MOCVD and other growth techniques can be used.

The invention disclosed herein allows expansion of the solid state low-noise amplifier operation above the 300 GHz region. Also, the invention facilitates high speed divide circuits operated at 80 GHz while consuming as little as 6 mW dc power or achieve multiplexing/demultiplexing at more than 80 Gbps and new generation of mixed signal circuits, such as an 8-bit A/D converter. These high speed, high frequency components greatly expand the use of the electromagnetic spectrum to enable unprecedented wideband wireless communications and data links for military, space, and civilian systems. The low power consumption electronics make several highly sought-after military and commercial applications feasible.

Wearable electronics equips a citizen and a soldier with a full range of real-time communications, situation awareness, and tele-medicine capability. Ultra low power electronics increase the micro UAV's dwell time and performance and makes many long-life portable military and commercial systems feasible and affordable. Sub-millimeter wave solid state low noise amplifiers enable real-time atmospheric spectral analysis for biological agents, battlefield meteorology and space exploration. Higher frequency digital electronics provides the next generation high speed Internet backbone as well as lower cost network distribution.

The invention disclosed herein includes next generation high speed, low power, digital mixed signal, and radio frequency integrated circuits capable of quadrupling speed and reduce power requirement by ten times for a 100-fold improvement in power-delay products over prior art. As in other systems, high speed and low power dissipation are major drivers.

The characteristics of the invention disclosed herein are responsive to demands of the Internet data traffic which doubles every six months. This explosion in demand requires a revolution in higher speed electronics.

HBT devices, particularly transistors, are fabricated by combining the inherent low power and high speed of 6.1 A materials that can result in devices that are twice as fast and consume ten times less power than prior art devices. These devices include transistors having disposed on a BaF₂ substrate semiconducting compounds with lattice constants in the range from 6 to 6.5 Å and GaSb-based transistors having lattice constants from 6.095 to 6.3 A. The device-level challenge is meeting the high speed (f_{T} and fₘₐₓ), low power (V_{BE} and V_{K}), and moderate breakdown requirements simultaneously. Performance is achievable for transistors with the highest (unity gain cut off frequency) f_{T} while maintaining the (Maximum frequency of oscillation) fₘₐₓ about equal to f_{T}, at base emitter voltage bias, V_{BE,} and knee voltage, V_{K,} each less than 5V, and collector emitter breakdown voltage, BV_{CEO,} of greater than 2 volts. The ability to deposit the HBT layers on the insulating BaF₂ substrate provides more benefits than on a semi-insulating substrate eliminating most of the stray parasitic capacitance. The fact that lattice matched and near lattice matched layers can be grown warrants high crystalline quality with reduced dislocations and point defects in the material. The HBT is a vertical current flow device and it is particularly vulnerable to dislocations. Lattice misfit dislocations are therefore eliminated by using a lattice matched substrate. HBTs are also by nature able to deliver more power. The ability to use a different composition ternaries and quaternaries allows the exploitation of a plethora of band alignments that can be readily used for having pnp and npn HBTs on the same substrate facilitating the direct application of high power delivery High frequency, low power dissipation Integrated circuits.

HEMT devices, particularly transistors, are fabricated by also using the 6.1 Å materials and result in devices that have cutoff frequency of 1 T Hz and consume ten times less power while achieving high yield. These devices include InAs-based channel transistors with lattice constant near 6.1 Å and Sb-based-channel transistors with lattice constant near 6.3 Å which have highest speed and require lowest power of any semiconducting technology.

To achieve the challenging f_{T}, transconductance, Gm, and low dc power requirements, the HEMT channel layer must have high mobility, saturated velocity, and carrier concentration. InAs channels have shown extremely high room temperature mobilities greater than 20,000 cm²/V-sec. The incorporation of Sb-based channels like the highest mobility InSb layers by itself or as ternaries, such as InGaSb and InAsSb, can provide advantages in mobility and saturated velocity and can provide further advantages in higher conduction band and valence band discontinuity. Sb-based channel materials have more risk because they are less understood with respect to growth feasibility and material properties compared to InAs channels. However, potential performance benefits of Sb-based channels warrant investing in their development.

The gate process is the most critical step in the fabrication of HEMTs. To achieve ultimate frequency performance, submicron, 30 and 50 nm T-gate length processes can be used. To achieve over 200 GHz f_{T} performance, developing a high yield 30 nm gate length process is necessary. Another step in the gate process is the choice of gate metal to achieve the best breakdown, lowest gate leakage and highest reliability. High barrier metals, such as Ti, Pt, Mo, TiN and TiW should be used. Evaporated TiW/Au gate process composed of 40% Ti has already been demonstrated to be operational which has demonstrated good thermal stability up to 270° C. on the 6.1 Å HEMTs. So far the HEMTs demonstrated in the antimonide material system are severely hindered by the presence of substantial leakage current in the off position. The leakage current is in general a result of the presence of a conducting path between the gate and drain region. Therefore The most critical item in achieving the low leakage current required for a marketable HEMT containing 6.1 Å lattice constant compounds, is the presence of a semi-insulating non conducting substrate and the high crystalline quality of the buffer and subsequent layers. High quality of the semiconductor layers can be achieved with crystalline material free of dislocations and point defects that provide leakage paths between the gate and drain region under normal operation. The BaF₂ substrate provides a solution for all these requirements. An insulating and a lattice matched substrate that allows for device isolation and elimination of substrate conduction paths and high quality crystalline growth in a lattice matched substrate. Possible surface leakage current can be addressed with conventional passivation techniques.

Low noise amplifier circuit performance requires a device with an extremely high cutoff frequency and a device operating at ultra low dc power. Based on requirements of each application, the InAs-channel and Sb-channel structures have the potential for the highest f_{T} exceeding 1 T Hz and breakdown voltage greater than 2V .

This invention also enables new missions that significantly impact understanding of atmospheric chemistry and thermodynamics, allowing for short and long-term monitoring of climate variability on continental and global scales. Technology based on this invention allows for low noise devices at frequencies of up to 350 GHz enabling the application of array techniques to achieve unprecedented spectral and spatial coverage of multiple atmospheric constituent molecules. The ability to generate power at higher frequencies permits integration of local oscillators directly into the receivers, reducing the cost, complexity and power consumption and simplifies heterodyne instruments at frequencies greater than 1 T Hz.

Infrared Optoelectronic devices, lasers sensors as well as photovoltaic devices will be also benefiting from the incorporation of BaF₂ substrates. For optical devices, BaF₂ is transparent over a large band of wavelength allowing implementation of transmission mode devices. Similarly, the incorporation of BaF₂ substrates allows the exploration of the large band gap availability of the Sb containing devices, ranging from 1.7 to 0.2 eV, in photovoltaic devices like monolithic tandem solar cells, as well as detectors and sensors.

While presently preferred embodiments have been shown of the novel electronic devices, and of the several modifications discussed, persons skilled in this art will readily appreciate that various additional changes and modifications may be made without departing from the spirit of the invention as defined and differentiated by the following claims.

What is claimed:

1. An electronic device comprising a BaF₂ substrate and at least two semiconducting layers disposed on said substrate.

2. The device of claim 1 including a contact surface on said substrate on which are disposed said semiconducting layers, said contact surface is face centered cubic and its crystallographic structure is selected from the group consisting of (100) and (111).

3. The device of claim 2 wherein said semiconducting layer in contact with said substrate is selected from compounds of elements selected from Groups II, III, IV, V and VI of the Periodic Table.

4. The device of claim 3 wherein said compounds are selected from the group consisting of InAs, GaSb, AlSb, InSb, InP, ZnTe, CdSe, ZnSe, CdTe and mixtures thereof.

5. The device of claim 3 wherein said compounds are selected from the group consisting of GaSb, InSb, AlSb, InAs, InP and mixtures thereof.

6. The device of claim 3 wherein said compounds are selected from the group consisting of GaSb, InSb, AlSb, InAs, InP and mixtures thereof.

7. The device of claim 5 wherein lattice constants of said contact surface and said semiconducting layer in contact with said substrate are within 5% of each other.

8. The device of claim 5 wherein lattice constants of said contact surface and said semiconducting layer in contact with said substrate are within 4% of each other.

9. The device of claim 5 wherein lattice constants of said additional semiconductor layers contain thin layers of larger or smaller lattice constants than 5% of each other and are in contact of each other and with the within 5% lattice matched layers.

10. The device of claim 8 wherein lattice constants of said additional semiconductor layers contain thin layers of semiconductors with larger or smaller lattice constants than 4% of each other and are in contact of each other and with the within 4% lattice matched layers.

11. The device of claim 9 wherein lattice constants of said additional semiconductor layers contain thin layers of semiconductors with larger or smaller lattice constants than 5% of each other and are in contact of each other and with the within 5% lattice matched layers.

12. The device of claim 1 including a contact surface on said substrate on which is disposed one of said semiconducting layers, said contact surface is face centered cubic and its crystallographic orientation is (100).

13. The device of claim 12 wherein said semiconducting layer in contact with said substrate is selected from compounds of elements selected from the group consisting of elements of Groups III and V of the Periodic Table.

14. The device of claim 12 wherein said semiconducting layer in contact with said substrate is selected from the antimonide family.

15. The device of claim 12 wherein said semiconducting layer in contact with said substrate is selected from compounds of elements selected from the group consisting In, Al, Ga, As Sb, and P.

16. An electronic device capable of operating at high frequency in the T Hz region, at low power loss that is at least 50% less that of any prior art device, and at low voltage of below 1 volt, the device comprising a BaF₂ contact substrate surface that is face centered cubic and its crystallographic structure is (100) and at least two semiconducting layers disposed thereon

17. The device of claim 16 wherein the semiconducting layer in contact with said substrate is selected from compounds of elements selected from the group consisting of Groups III and V of the Periodic Table.

18. The device of claim 16 wherein the semiconducting layer in contact with said substrate is selected from compounds of elements selected from the group consisting of In, Al, Ga, As, Sb and P.

20. The device of claim 17 wherein said compound is selected from binary, ternary and quaternary compounds.

21. The device of claim 18 wherein said contact surface is epitaxial growth ready.

22. The device of claim 20 wherein said contact surface is devoid of an oxide.

23. The device of claim 17 wherein said semiconducting layers include a buffer layer disposed on said substrate, a channel layer or layers disposed above said buffer layer, and a contact layer disposed above said channel layer.

24. The device of claim 17 wherein said semiconducting layers include a collector layer disposed on said substrate, a base layer disposed above said collector layer, and an emitter layer disposed above said base layer.

25. The device of claim 17 wherein said semiconducting layers include in contact two different type of doping layers optically sensitive in the Infrared wavelength region.

26. The device of claim 17 wherein said semiconducting layers include in contact multiple alternating type of doping layers optically sensitive from the visible to the Infrared wavelength region.
